(19) United States
(12) Patent Application Publication
(10) Pub. No.: US 2017/0223869 A1
(43) Pub. Date: Aug. 3, 2017

(54) COOLING DEVICE AND COOLING DEVICE MANUFACTURING METHOD

(71) Applicant: SANOH INDUSTRIAL CO., LTD., Tokyo (JP)

(72) Inventors: Yoshitaka Shibasaki, Koga-shi (JP); Takuma Endo, Koga-shi (JP); Takeo Oguri, Koga-shi (JP); Katsutoshi Ishibashi, Koga-shi (JP)

(21) Appl. No.: 15/115,117

(22) PCT Filed: Oct. 28, 2014
(86) PCT No.: PCT/JP2014/078656

§ 371 Date: Jul. 28, 2016

(30) Foreign Application Priority Data
Feb. 25, 2014 (JP) 2014-034508

(51) Int. Cl. H05K 7/20; F28F 9/00; F28F 3/12; H01L 23/473; H01L 21/48

(52) U.S. Cl. CPC H05K 7/20263; H05K 7/20436; H01L 23/4735; H01L 21/4882; F28F 3/12; F28F 9/001; F28F 2240/00; F28F 2265/32; F28F 2275/04; F28F 2275/14

(57) ABSTRACT

A cooling device includes: a case that includes a supply port for supplying coolant to an interior of the case and a discharge port for discharging coolant at the interior of the case to an exterior of the case; fins that each have a plate shape, that are arrayed at the interior of the case at separations along a plate thickness direction, and that have coolant flowing between adjacent fins; a maintenance portion that is formed at the fins and that maintains a separation between the adjacent fins; and a restraint portion that is formed at the fins and that restrains relative movement of the adjacent fins being maintained at the separation by the maintenance portion.

### TECHNICAL FIELD

The present invention relates to a cooling device and a cooling device manufacturing method.

### BACKGROUND ART

Japanese Patent Application Laid-Open (JP-A) No. 2007-335588 describes a liquid cooling type of cooling device (heat sink) in which plate shaped fins are arrayed at an interior of a case, and the fins are joined to an inner face of the case.

### SUMMARY OF INVENTION

### Technical Problem

However, in cases in which positional misalignment of the fins has occurred during manufacturing, sometimes a desired cooling performance cannot be obtained, namely, there is a drop in cooling performance.

In consideration of the above circumstances, an issue of the present invention is to provide a cooling device and a cooling device manufacturing method that improve cooling performance, while suppressing positional misalignment of fins.

### Solution to Problem

A cooling device of a first aspect of the present invention includes: a case that includes a supply port for supplying coolant to an interior of the case and a discharge port for discharging coolant at the interior of the case to an exterior of the case; fins that each have a plate shape, that are arrayed at the interior of the case at separations along a plate thickness direction, and that have coolant flowing between adjacent fins; a maintaining means that is formed at the fins and that maintains a separation between the adjacent fins; and a restraining means that is formed at the fins and that restrains relative movement of the adjacent fins being maintained at the separation by the maintaining means.

In the cooling device of the first aspect, heat from a cooling target is transferred to the case and the fins by disposing the cooling target so as to contact the case. The case and the fins are cooled by coolant supplied into the case. The heat of the cooling target is thereby captured by the coolant, and the cooling target is cooled.

Note that in the above cooling device, by installing the fins at the interior of the case in a state in which relative movement of adjacent fins has been restrained by the restraining means while maintaining the separation between adjacent fins using the maintaining means during manufacturing, relative positional misalignment of adjacent fins can be suppressed, while securing the separation between adjacent fins. The flow of coolant at the interior of the case is thereby brought closer to the desired flow, enabling cooling performance to be improved.

Thus, the cooling device of the first aspect enables cooling performance to be improved, while suppressing positional misalignment of the fins.

A cooling device of a second aspect of the present invention is the cooling device of the first aspect in which the maintaining means includes a projecting portion that projects out in the plate thickness direction of the fins and that has an apex portion that abuts a fin that is adjacent at one side in an array direction of the fins, and the restraining means includes a bulge portion that projects out from the apex portion of the projecting portion and an insertion portion into which the bulge portion of a fin that is adjacent at another side in the array direction of the fins is inserted.

In the cooling device of the second aspect, relative movement of adjacent fins is restrained by inserting the bulge portion of a fin into the insertion portion of the fin that is adjacent at the one side in the fin array direction during manufacturing. The separation between adjacent fins is secured by making the apex portion of the projecting portion of a fin abut the fin that is adjacent at the one side in the fin array direction.

Note that, since the maintaining means is configured as a projecting portion that projects out in the fin plate thickness direction and abuts the fin that is adjacent at the one side in the fin array direction, the separation between adjacent fins can be secured (maintained) using a simple structure. Since the restraining means is configured by the bulge portion that projects out from the apex portion of the projecting portion, and the insertion portion into which the bulge portion of the fin that is adjacent at the other side in the fin array direction is inserted, adjacent fins can be restrained using a simple structure.

Since the bulge portion is formed at the apex portion of the projecting portion, the height of the bulge portion (projection height) can be made lower than, for example, configurations in which the bulge portion is formed at a separate location to the apex portion of the projecting portion, or to the projecting portion, such that processing of the fins is easier. Note that the separation between adjacent fins can be adjusted by adjusting the height of the projecting portion. This enables the flow rate of coolant flowing between adjacent fins to be adjusted (increased), improving cooling performance.

A cooling device of a third aspect of the present invention is the cooling device of the second aspect in which the projecting portion is a tube shaped protruding portion formed by pressing the fins, and an interior of the projecting portion configures the insertion portion.

In the cooling device of the third aspect, the projecting portion is a tube shaped protruding portion formed by pressing the fin. This enables the projecting portion to be formed at the fin more simply and at a lower cost than, for example, configurations in which a projecting portion is formed at a fin while the fin is formed by being machined, or configurations in which an additional component is joined to a fin to form a projecting portion.

A cooling device of a fourth aspect of the present invention is the cooling device of the second aspect or the third aspect, in which the projecting portion, the bulge portion, and the insertion portion are each formed at both end portion sides along a length direction of the fins.

In the cooling device of the fourth aspect, the projecting portion, the bulge portion, and the insertion portion are each formed at both end portion sides in the length direction of each fin. This enables relative positional misalignment of adjacent fins to be effectively suppressed, while securing a substantially uniform separation between adjacent fins along the fin length direction.

A cooling device of a fifth aspect of the present invention is the cooling device of any one of the first aspect to the fourth aspect, in which end faces of the fins are brazed to an inner face of the case.

In the cooling device of the fifth aspect, the end faces of the fins are brazed to the inner face of the case, thereby improving the rigidity of the case. This also improves the heat transfer efficiency between the fins and the case.

A cooling device manufacturing method of a sixth aspect of the present invention includes: an assembly process of assembling together fins that are plate shaped and each formed with a projecting portion projecting out in a plate thickness direction, a bulge portion projecting out from an apex portion of the projecting portion, and an insertion portion of a size enabling internal insertion of the bulge portion, in which the fins are assembled together by inserting the bulge portion of one of the fins into the insertion portion of another of the fins, and abutting the projecting portion of the one fin against the other fin; and an installation process of installing the fins at an interior of a case including a supply port for supplying coolant to the interior of the case, and a discharge port for discharging coolant at the interior of the case to an exterior of the case.

In the cooling device manufacturing method of the sixth aspect, in the assembly process, the apex portion of the projecting portion of a fin is made to abut another fin and the fins are assembled together while inserting the bulge portion of the fin into the insertion portion of the other fin to restrain relative movement of the fins, such that the positioning of the fins is easily performed.

In the installation process, the fins that have been assembled in the above manner are installed at the interior of the case, thereby enabling relative positional misalignment of the fins to be suppressed. This also enables the separation between the assembled fins to be secured (maintained).

A cooling device manufactured in this manner brings the flow of coolant at the interior of the case closer to the desired flow, thereby enabling cooling performance to be improved.

Thus, the cooling device manufacturing method of the sixth aspect enables manufacture of a cooling device that improves cooling performance, while suppressing positional misalignment of the fins.

A cooling device manufacturing method of a seventh aspect is the cooling device manufacturing method of the sixth aspect, further including, prior to the assembly process, a working process of forming a tube shaped protruding portion, serving as the projecting portion and including the insertion portion configured at an interior thereof, by pressing a plate shaped un-processed fin.

In the cooling device manufacturing method of the seventh aspect, in the working process, the tube shaped protruding portion serving as the projecting portion is formed by pressing the un-processed fin to form the work-processed fin. This enables the projecting portion to be formed at the fin more simply and at a lower cost than, for example, configurations in which a projecting portion is formed at a fin while the fin is formed by being machined, or configurations in which an additional component is joined to a fin to form a projecting portion.

A cooling device manufacturing method of an eighth aspect is the cooling device manufacturing method of the seventh aspect, in which, in the working process, the projecting portion, the bulge portion, and the insertion portion are each formed at both end portion sides along a length direction of the un-processed fins.

In the cooling device manufacturing method of the eighth aspect, relative positional alignment of assembled fins after processing can be effectively suppressed by each forming the projecting portion, the bulge portion, and the insertion portion at both end portion sides along the length direction of the un-processed fin in the working process.

A cooling device manufacturing method of a ninth aspect is the cooling device manufacturing method of any one of the sixth aspect to the eighth aspect, in which, in the installation process, end faces of the fins are brazed to an inner face of the case.

In the cooling device manufacturing method of the ninth aspect, end faces of the fins are brazed to the inner face of the case in the installation process, thereby improving the rigidity of the case of the cooling device that has been manufactured in this manner, and also improving the heat transfer efficiency between the fins and the case.

### Advantageous Effects of Invention

As explained above, the present invention enables the provision of a cooling device and a cooling device manufacturing method that improve cooling performance while suppressing positional misalignment of the fins.

### BRIEF DESCRIPTION OF DRAWINGS

FIG. 1 is a perspective view of a cooling device of a first exemplary embodiment.

FIG. 2 is an exploded perspective view of a cooling device of the first exemplary embodiment.

FIG. 3 is a plan view of a lid body of a case of a cooling device of the first exemplary embodiment in an opened state.

FIG. 4 is a cross-section along line 4-4 in FIG. 1.

FIG. 5 is an enlarged partial cross-section of a portion indicated by the arrow 5 in FIG. 3.

FIG. 6 is a perspective view of fins employed in a cooling device of the first exemplary embodiment, illustrating an assembly operation of the fins.

FIG. 7 is a plan view illustrating a flow of coolant at an interior of a case of a cooling device of the first exemplary embodiment, in a state in which a lid body of the case has been opened.

FIG. 8 is a cross-section along line 8-8 in FIG. 7.

FIG. 9 is a plan view of an assembled state of fins employed in a cooling device of a second exemplary embodiment.

FIG. 10 is an enlarged partial cross-section of a portion indicated by the arrow 10 in FIG. 9.

FIG. 11 is a partial plan view illustrating a flow of coolant at an interior of a case of a cooling device of the second exemplary embodiment, in a state in which a lid body of the case has been opened.

FIG. 12 is a plan view of an assembled state of fins employed in a cooling device of a third exemplary embodiment.

FIG. 13 is an enlarged partial cross-section of a portion indicated by the arrow 13 in FIG. 12.

FIG. 14 is a face-on view of a fin employed in a cooling device of the third exemplary embodiment.

FIG. 15 is a cross-section corresponding to FIG. 8, illustrating a flow of coolant at an interior of a case of a cooling device of the third exemplary embodiment.

FIG. 16 is a perspective view of fins employed in a cooling device of a fourth exemplary embodiment, illustrating an assembled state of the fins.

FIG. 17 is a plan view of an assembled state of fins employed in a cooling device of the fourth exemplary embodiment.

FIG. 18 is an enlarged partial cross-section of a portion indicated by the arrow 18 in FIG. 17.

FIG. 19 is a cross-section corresponding to FIG. 8, illustrating a flow of coolant at an interior of a case of a cooling device of the fourth exemplary embodiment.

FIG. 20 is a plan view illustrating a flow of coolant at an interior of a case of a cooling device of a fifth exemplary embodiment, in a state in which a lid body of the case has been opened.

FIG. 21 is an enlarged partial cross-section view corresponding to FIG. 5, illustrating an assembled state of fins of a modified example of fins employed in a cooling device of the first exemplary embodiment.

FIG. 22 is an enlarged partial cross-section view corresponding to FIG. 5, illustrating an assembled state of fins employed in a cooling device of a sixth exemplary embodiment.

FIG. 23 is an enlarged partial cross-section view corresponding to FIG. 5, illustrating an assembled state of fins of a first modified example of fins employed in a cooling device of the sixth exemplary embodiment.

FIG. 24 is an enlarged partial cross-section view corresponding to FIG. 5, illustrating an assembled state of fins of a second modified example of fins employed in a cooling device of the sixth exemplary embodiment.

### DESCRIPTION OF EMBODIMENTS

Explanation follows regarding a cooling device and a cooling device manufacturing method of exemplary embodiments according to the present invention, with reference to the drawings. Note that the arrow X, arrow Y, and arrow Z illustrated in each of the drawings as appropriate respectively indicate the device width direction, the device depth direction, and the device thickness direction of the cooling device, and explanation follows with the arrow Z direction as the up-down direction.

### First Exemplary Embodiment

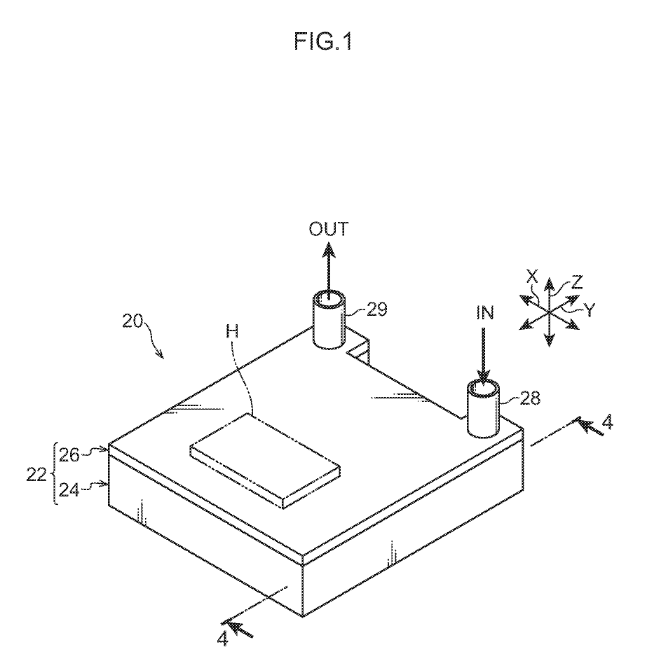

FIG. 1 illustrates a cooling device 20 of a first exemplary embodiment (hereafter referred to as present exemplary embodiment). The cooling device 20 is employed to cool a heat generating body (a cooling target) such as a CPU or power semiconductor elements. Specifically, the cooling device 20 is placed in contact with a heat generating body H, and the heat generating body H is cooled by transferring the heat of the heat generating body H to a coolant flowing at an interior of the cooling device 20.

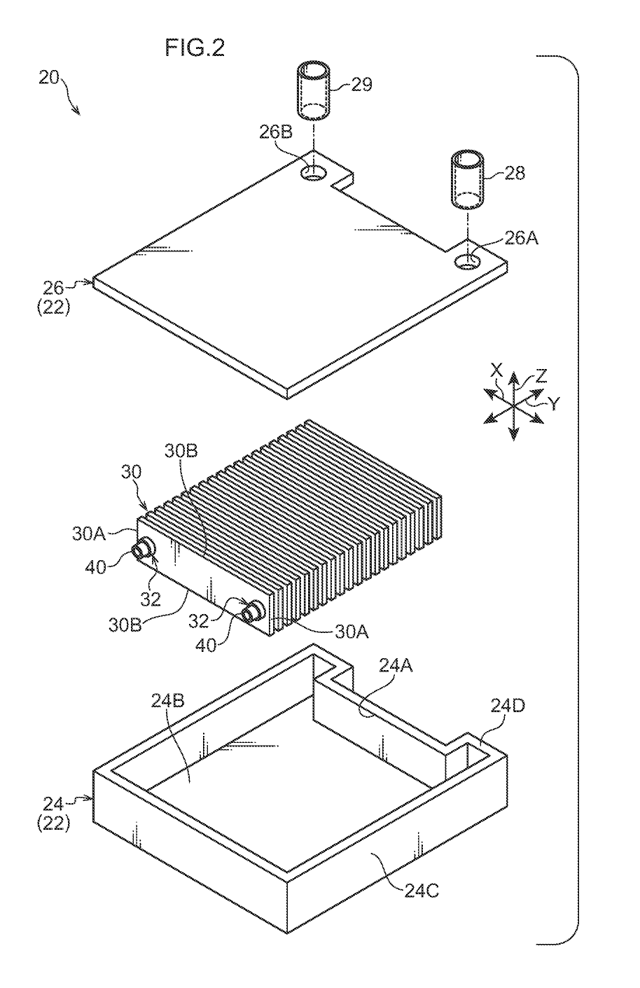

As illustrated in FIG. 1 and FIG. 2, the cooling device 20 of the present exemplary embodiment includes a case 22, and fins 30 installed at an interior of the case 22.

As illustrated in FIG. 2, the case 22 includes a case main body 24, and a lid body 26 that closes off an opening 24A in the device thickness direction of the case main body 24.

The case main body 24 is configured by a plate shaped bottom portion 24B, and a side wall portion 24C that projects upward at an outer peripheral edge of the bottom portion 24B. The case main body 24 is formed using a metal material (such as aluminum or copper).

As illustrated in FIG. 1 and FIG. 2, the lid body 26 has a plate shape, and is joined to an end face 24D at the opposite side of the side wall portion 24C of the case main body 24 to the bottom portion 24B side. Note that in the present exemplary embodiment, the lid body 26 is joined to the end face 24D of the case main body 24 by brazing. The lid body 26 is also formed using a metal material (such as aluminum or copper).

A supply port 26A for supplying coolant (such as cooling water or oil) into the case 22 is formed at one end side in the device width direction of the lid body 26. A supply pipe 28 (see FIG. 1) that is coupled to a coolant supply source is connected to the supply port 26A.

A discharge port 26B for discharging coolant from the interior to an exterior of the case 22 is formed at another end side in the device width direction of the lid body 26. A discharge pipe 29 (see FIG. 1) is connected to the discharge port 26B.

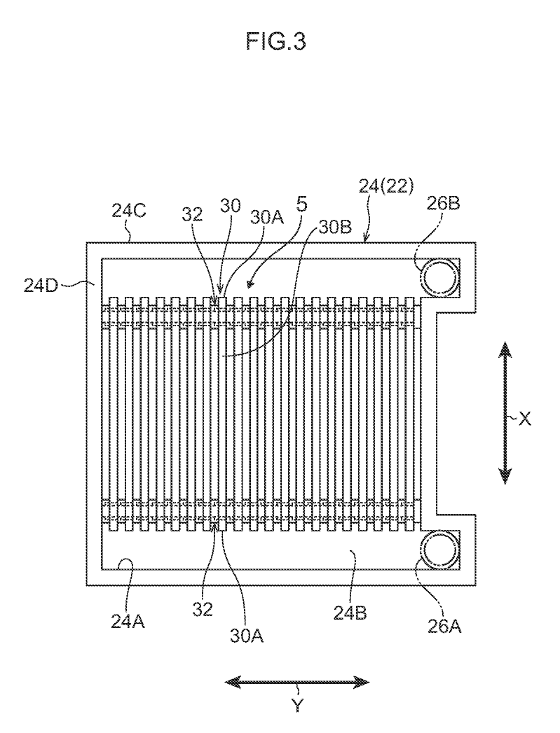

As illustrated in FIG. 3 to FIG. 5, the fins 30 are each configured in an elongated, flat plate shape, and plural of the fins 30 are arrayed at the interior of the case 22 at separations along a fin plate thickness direction (the same direction as the device depth direction in the present exemplary embodiment). The fins 30 are formed using a metal material (such as aluminum or copper). The fin length direction of the fins 30 in the present exemplary embodiment is the same direction as the device width direction.

Projecting portions 32 that project out along the fin plate thickness direction are formed at each fin 30. Each projecting portion 32 is a tube shaped (circular tube shaped in the present exemplary embodiment) and an apex portion 32A that abuts the fin 30 that is adjacent at one side (the left in FIG. 3 to FIG. 5) in a fin array direction (the same direction as the fin plate thickness direction). Note that a separation between adjacent fins 30 can be maintained by making the apex portion 32A of the projecting portion 32 abut the fin 30 that is adjacent at the one side in the fin array direction. Note that the projecting portions 32 of the present exemplary embodiment are an example of a maintaining means of the present invention.

Each projecting portion 32 is a circular tube shaped protruding portion that is formed on the each fin 30 by pressing. An insertion portion 32B, described later, is configured at an interior of the projecting portion 32.

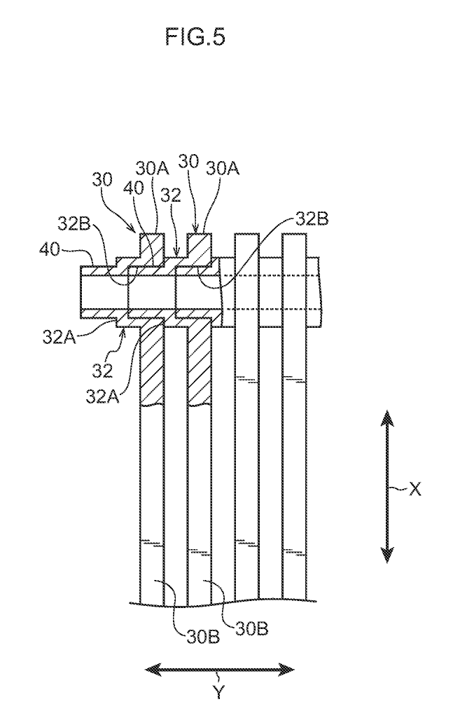

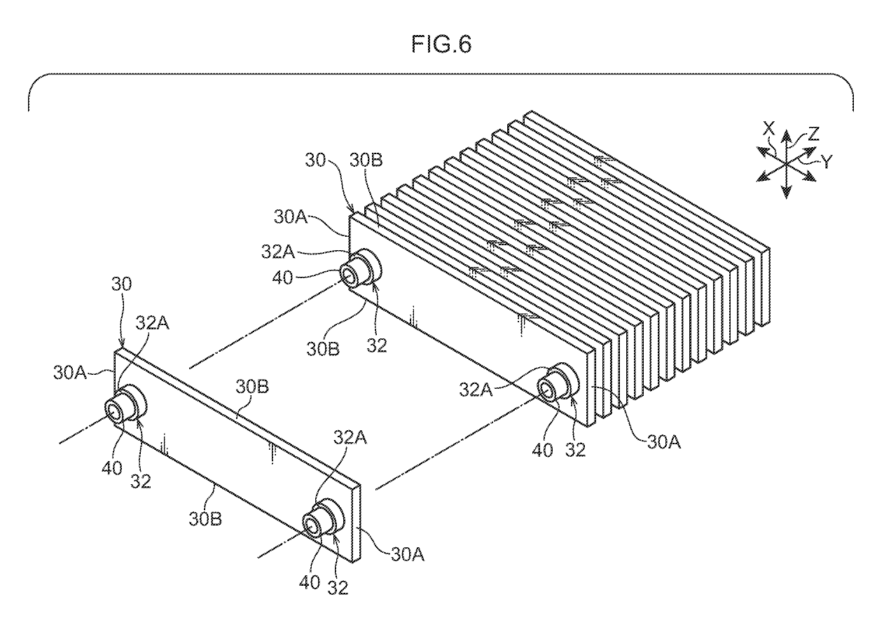

As illustrated in FIG. 5 and FIG. 6, a bulge portion 40 that projects out in the fin plate thickness direction from a substantially central portion of the apex portion 32A in a tube shape (a circular tube shape in the present exemplary embodiment) is formed on the apex portion 32A of each projecting portion 32. Note that, similarly to the projecting portion 32, the bulge portion 40 is a protruding portion formed at the each fin 30 by pressing, but has a smaller diameter than the projecting portion 32.

The fin 30 is also formed with the insertion portion 32B, into which the bulge portion 40 of the fin 30 that is adjacent at another side (the right in FIG. 3 to FIG. 5) in the fin array direction at the opposite side to the side at which the projecting portion 32 is formed is inserted. Note that, as previously described, the insertion portion 32B is configured at the interior of the projecting portion 32. An inner diameter of the insertion portion 32B is set so as to have the same, or a slightly larger diameter than an outer diameter of the bulge portion 40. Thus, in a state in which the bulge portion 40 of the fin 30 that is adjacent at the other side in the fin array direction has been inserted into the insertion portion 32B of the fin 30 (an inserted state), an inner wall face of the insertion portion 32B and an outer wall face of the bulge portion 40 contact each other, and relative movement of adjacent fins 30 is restrained. Note that, the bulge portions 40 and the insertion portions 32B of the present exemplary embodiment are an example of a restraining means of the present invention.

In the present exemplary embodiment, when the apex portion 32A of the projecting portion 32 has abutted the fin 30 that is adjacent at the one side in the fin array direction, the bulge portion 40 is inserted into the insertion portions 32B of the fin 30 that is adjacent at the one side in the fin array direction. Thus, in a state in which a separation between adjacent fins 30 has been maintained, relative movement of adjacent fins 30 is restrained (relative movement in a direction orthogonal to the fin plate thickness direction in the present exemplary embodiment).

The projecting portions 32, the bulge portions 40, and the projecting portions 32 are each formed at both end portion 30A sides in the length direction of each fin 30.

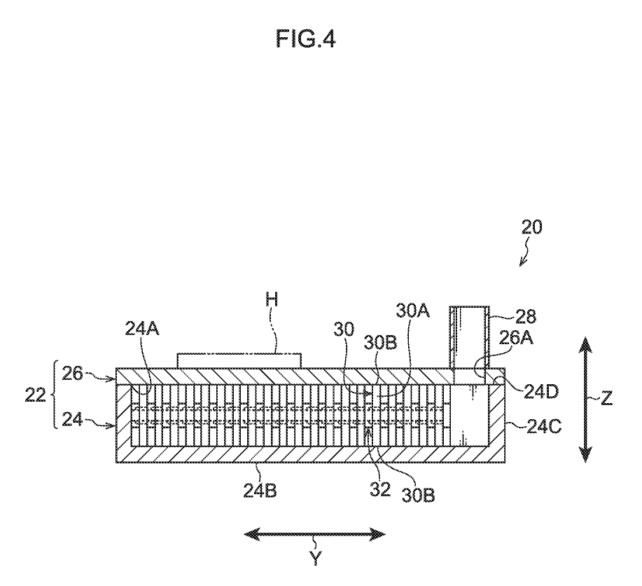

As illustrated in FIG. 4, both end faces 30B in a fin width direction (the same direction as the device thickness direction in the present exemplary embodiment) of each fin 30 are each joined to an inner face (bottom face) of the bottom portion 24B of the case 22 and to an inner face (ceiling face) of the lid body 26, and the fins 30 are installed at the interior of the case.

Note that in the present exemplary embodiment, both end faces 30B in the fin width direction of each fin 30 are each joined to the inner face of the bottom portion 24B of the case 22 and to the inner face of the lid body 26 by brazing.

As illustrated in FIG. 3 and FIG. 4, the each apex portions 32A of the projecting portions 32 at both sides of the fin 30 positioned at one end in the fin array direction of the assembled fins 30 abut and are fixed to an inner face at one side in the device depth direction of the side wall portion 24C. Note that the fin 30 positioned at the one end in the fin array direction is a fin in which the bulge portion 40 is not formed on the apex portion 32A of each projecting portion 32.

Fixing members 44, each with a circular column shape, are inserted into the each insertion portions 32B of the fin 30 positioned at another end in the fin array direction of the assembled fins 30. End portions of the fixing members 44 abut and are fixed to the inner face at another side in the device depth direction of the side wall portion 24C.

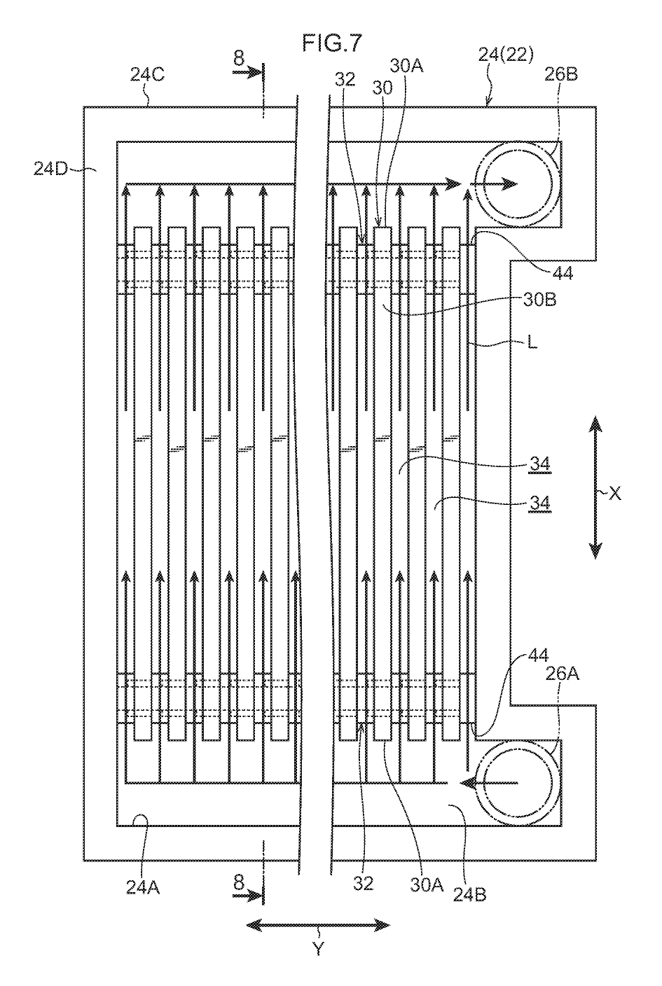

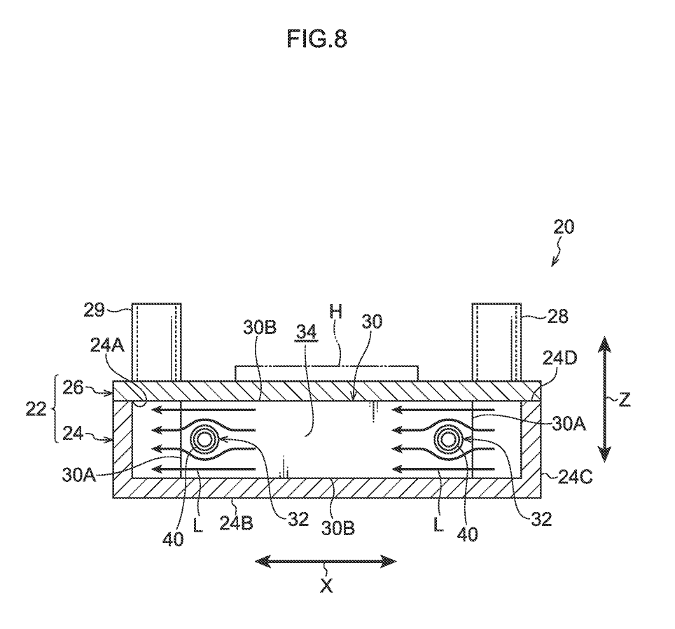

As illustrated in FIG. 7 and FIG. 8, in the present exemplary embodiment, a separation between adjacent fins 30 (a projection height of the projecting portions 32) is set at a size enabling coolant to flow from the supply port 26A toward the discharge port 26B.

Next, explanation follows regarding a manufacturing method of the cooling device 20 of the present exemplary embodiment.

### Working Process

First, pilot holes are opened up in an un-processed fin 30 formed of metal material in a plate shape. The protruding tube shaped (circular tube shaped in the present exemplary embodiment) projecting portion 32, and the tube shaped (circular tube shaped in the present exemplary embodiment) bulge portion 40 that projects out from the apex portion 32A of the projecting portion 32, are formed at a peripheral portion of each pilot hole by pressing. When this is performed, the projecting portion 32 and the bulge portion 40 are formed such that an inner diameter of the projecting portion 32 is the same or slightly larger than the outer diameter of the bulge portion 40. The bulge portion 40 of the work-processed fin 30 is thereby capable of being inserted at the interior (the insertion portion 32B) of the projecting portion 32 of another work-processed fin 30.

The projecting portions 32 and the bulge portions 40 are each formed at both end portion 30A sides in the fin length direction of the un-processed fin 30.

Note that “un-processed fin 30” refers to a state of each fin 30 prior to the working process (prior to opening up the pilot holes in the present exemplary embodiment). Moreover, “work-processed fin 30” refers to a state of each fin 30 after the working process (after the projecting portions 32 and the bulge portions 40 have been formed in the present exemplary embodiment). Note that the work-processed fin 30 is simply referred to as fin 30.

### Assembly Process

Next, as illustrated in FIG. 6, the bulge portions 40 of each fin 30 are each inserted into the insertion portions 32B of another fin 30. When this is performed, the fins 30 are assembled to each other by each inserting the bulge portions 40 of each fin 30 into the insertion portions 32B of another fin 30 until the apex portions 32A of the projecting portions 32 of the fin 30 abut the other fin 30.

Note that in the assembly process, the apex portions 32A of the projecting portions 32 of each fin 30 are made to abut another fin 30 and the fins 30 are assembled together in a state in which relative movement of the fins 30 has been restrained by inserting the bulge portions 40 of the fin 30 into the insertion portions 32B of the other fin 30, such that positioning of the fins 30 can be easily performed. A separation between the fins 30 is secured (maintained) by the projecting portions 32.

### Installation Process

Next, the assembled fins 30 are installed on the bottom portion 24B of the case main body 24 (the state illustrated in FIG. 3). The opening 24A of the case main body 24 is then closed off by the lid body 26. Both end faces 30B of each fin 30 each contact the inner face of the bottom portion 24B of the case 22 and the inner face of the lid body 26 when this is performed.

Both end faces 30B of each fin 30 are then each joined to the inner face of the bottom portion 24B of the case 22 and the inner face of the lid body 26 by brazing. Manufacturing of the cooling device 20 is completed in this manner.

Note that in the installation process, the fins 30 that have been assembled in the assembly process are installed at the interior of the case 22, thereby enabling relative positional misalignment (positional misalignment in a direction orthogonal to the fin plate thickness direction in the present exemplary embodiment) of the fins 30 to be suppressed. This also enables the separation between the assembled fins 30 to be secured (maintained).

Next, explanation follows regarding operation and advantageous effects of the cooling device 20 of the present exemplary embodiment.

As illustrated in FIG. 1, in the cooling device 20, by disposing the heat generating body H so as to contact the case 22, heat from the heat generating body H is transferred to the case 22 and also to the fins 30 through the case 22. The case 22 and the fins 30 are cooled by heat exchange with the coolant supplied into the case 22. The heat of the heat generating body H is captured by the coolant, and the heat generating body H is cooled in this manner.

Note that in the cooling device 20, the assembled fins 30 are installed at the interior of the case 22 during manufacturing (the assembly process), thereby enabling relative positional misalignment of adjacent fins 30 to be suppressed, while maintaining the separation between adjacent fins 30. Thus, the flow of coolant at the interior of the case 22 is brought closer to the desired flow, thereby enabling cooling performance to be improved.

In the cooling device 20, adjacent fins 30 can be restrained by a simple configuration in which the bulge portions 40 of each fin 30 are each inserted into the insertion portions 32B of the fin 30 that is adjacent at the one side in the fin array direction. Furthermore, the fins 30 can be assembled to each other by a simple operation in which the bulge portions 40 of each fin 30 are each inserted into the insertion portions 32B of another fin 30.

Since the bulge portion 40 is formed on the apex portion 32A of each projecting portion 32, the height of the bulge portion (projection height) can be lowered compared to, for example, cases in which a bulge portion is formed at a separate location to an apex portion of the projecting portion 32 or to the projecting portion 32, such that it is easy to work-process the fins 30.

Note that adjusting the height of the projecting portions 32 enables the separation between adjacent fins 30 to be adjusted. This accordingly enables a flow rate of coolant flowing between adjacent fins 30 to be adjusted (increased), and cooling performance to be improved.

Since each fin 30 is pressed to form the projecting portions 32, the bulge portions 40, and the insertion portions 32B, the projecting portions 32, the bulge portions 40, and the insertion portions 32B can be formed at the fin 30 more simply and at a lower cost than, for example, configurations in which the projecting portions 32, the bulge portions 40, and the insertion portions 32B are formed at the fin 30 while the fin 30 is formed by machining.

The projecting portions 32, the bulge portions 40, and the insertion portions 32B are each formed at both end portion 30A sides in the fin length direction of each fin 30, thereby enabling relative positional misalignment of adjacent fins 30 to be effectively suppressed. This also enables a substantially uniform distance (separation) between adjacent fins 30 to be reliably secured along the fin length direction. This further improves the cooling performance of the cooling device 20.

Both end faces 30B of each fin 30 are each joined by brazing to the inner face of the bottom portion 24B of the case 22 and the inner face of the lid body 26, thereby improving the rigidity of the case 22. This also improves the heat transfer efficiency between the fins 30 and the case 22, further improving the cooling performance of the cooling device 20.

As illustrated in FIG. 7 and FIG. 8, in the cooling device 20 of the present exemplary embodiment, the entrance to gaps (flow paths 34) formed between adjacent fins 30 is made narrower by the projecting portions 32 at the supply port 26A side. Thus, coolant that has been supplied through the supply port 26A flows substantially uniformly into the flow paths 34 that are at positions far away from the supply port 26A along the device depth direction. Thus, the fins 30 configuring the flow paths 34 that are at positions far away from the supply port 26A are also cooled by the coolant. This enables the heat generating body H that has been placed in contact with the cooling device 20 to be cooled substantially uniformly. Namely, in the cooling device 20 of the present exemplary embodiment, an advantageous effect of regulating the coolant can be obtained by the configuration of the fins 30. Note that the flow of coolant is illustrated by the arrows L in FIG. 7 and FIG. 8.

As described above, the cooling device 20 of the present exemplary embodiment enables cooling performance to be improved, while suppressing positional misalignment of the fins 30.

In the present exemplary embodiment, the projecting portions 32, the bulge portions 40, and the insertion portions 32B are formed on each fin 30 by pressing; however, the present invention is not limited to this configuration. For example, the projecting portions 32, the bulge portions 40, and the insertion portions 32B may be formed on a fin 30 that is formed by machining. Note that the above-described configuration may also be applied to the each fins described later in second, third, and fifth exemplary embodiments.

The present exemplary embodiment is configured such that the projecting portions 32, the bulge portions 40, and the insertion portions 32B are each formed at both end portion 30A sides in the fin length direction of each fin 30; however, the present invention is not limited to this configuration. For example, the projecting portions 32, the bulge portions 40, and the insertion portions 32B may be formed on a portion (such as a center portion) other than both end portion 30A sides in the fin length direction of each fin 30, or the projecting portion 32, the bulge portion 40, and the insertion portion 32B may be formed at only one end portion 30A side in the fin length direction of each fin 30. Note that the above-described configurations may also be applied the each fins described later in the second to fifth exemplary embodiments.

The present exemplary embodiment is configured such that the bulge portion 40 is formed on the apex portion 32A of each projecting portion 32; however, the present invention is not limited to this configuration. For example, the bulge portion 40 may be formed at a separate location to each projecting portion 32 of the fin 30. Note that the above-described configuration may also be applied the each fins described later in the second to fifth exemplary embodiments.

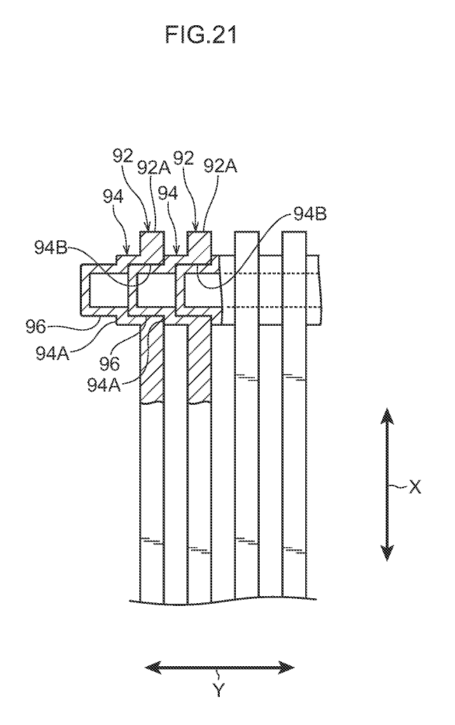

In the present exemplary embodiment as illustrated in FIG. 5, each bulge portion 40 has a tube shape; however, the present invention is not limited to this configuration. For example, as in the case of fins 92 illustrated in FIG. 21, these being a modified example of the fins 30, configuration may be such that a leading end portion in a projection direction of a bulge portion 96 that projects out from an apex portion 94A of a circular tube shaped projecting portion 94 is closed off. In such cases, there is no need for a pilot hole when work-processing the bulge portion 96, thereby enabling the number of processes for work-processing the fins 92 to be reduced. This also enables scrap material created by forming the pilot holes in the fins to be reduced. Note that the configuration of the fins 92 may also be applied to the each fins described later in the second, third, and fifth exemplary embodiments. The reference numerals 94B in FIG. 21 indicate insertion portions.

As illustrated in FIG. 5 and FIG. 6, in the present exemplary embodiment, the projecting portion 32 is configured in a circular tube shape; however, the present invention is not limited to this configuration. For example, the projecting portion 32 may be configured in a polygonal tube shape, an elliptical tube shape, a pyramidal tube shape, a conical tube shape, or the like. Note that the above-described configurations may also be applied the each fins described later in the second, third, and fifth exemplary embodiments.

In the present exemplary embodiment, as illustrated in FIG. 5 and FIG. 6, each bulge portion 40 has a circular tube shape; however, the present invention is not limited to this configuration. For example, the bulge portion 40 may have a polygonal tube shape, an elliptical tube shape, a pyramidal tube shape, or a conical tube shape. In such cases, the bulge portions 40 of each fin 30 can be inserted into the insertion portions 32B of another fin 30 by forming the insertion portions 32B in a shape corresponding to that of the bulge portions 40. Note that the above configuration may also be applied to the each fins described later in the second, third, and fifth exemplary embodiments.

### Second Exemplary Embodiment

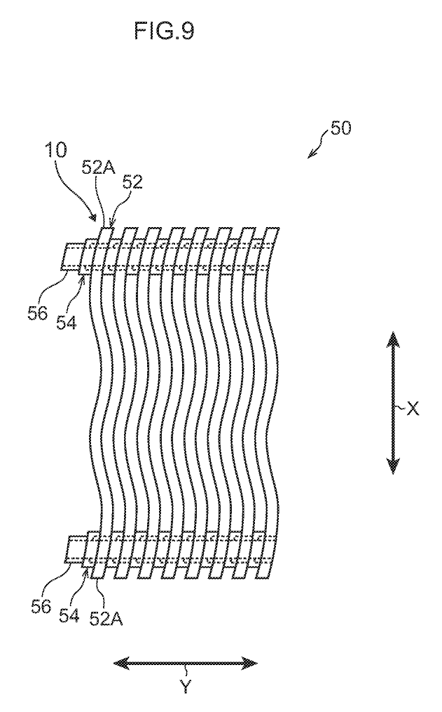

FIG. 9 to FIG. 11 illustrate a cooling device 50 of the second exemplary embodiment. Note that the cooling device 50 of the present exemplary embodiment has a similar configuration to the cooling device 20 of the first exemplary embodiment excluding the configuration of fins 52, and so similar explanation is omitted. Note that similar configuration to the first exemplary embodiment is appended with the same reference numerals.

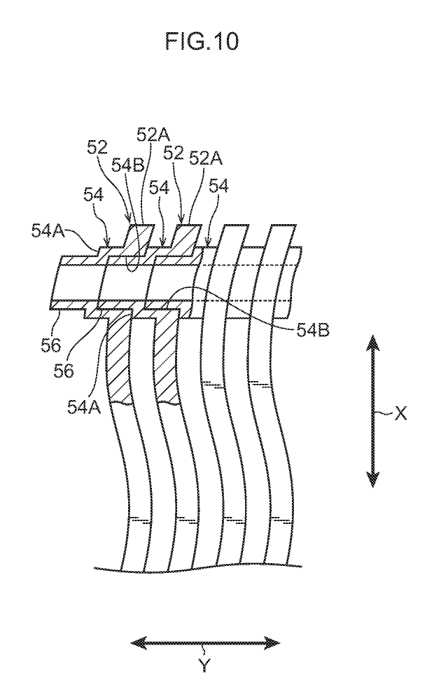

As illustrated in FIG. 9 and FIG. 10, each fin 52 has an elongated wave plate shape. Note that the fin length direction of the fins 52 of the present exemplary embodiment is the same direction as the device width direction, and each fin 52 has a wave plate shape with amplitude that moves to the left and right (in the fin plate thickness direction) along the fin length direction. Tube shaped (circular tube shaped in the present exemplary embodiment) projecting portions 54, and tube shaped (circular tube shaped in the present exemplary embodiment) bulge portions 56 that project out from each apex portions 54A of the projecting portions 54, are each formed by pressing at both end portion 52A sides in the fin length direction of each fin 52. The insertion portions 54B configured at an interior of the projecting portions 54 are each inserted with the bulge portions 56 of the fin 52 that is adjacent at the other side in the fin array direction (the right in FIG. 9 to FIG. 11).

Next, explanation follows regarding operation and advantageous effects of the cooling device 50 of the present exemplary embodiment. Note that explanation regarding operation and advantageous effects that are similar to the operation and advantageous effects obtained in the first exemplary embodiment is omitted.

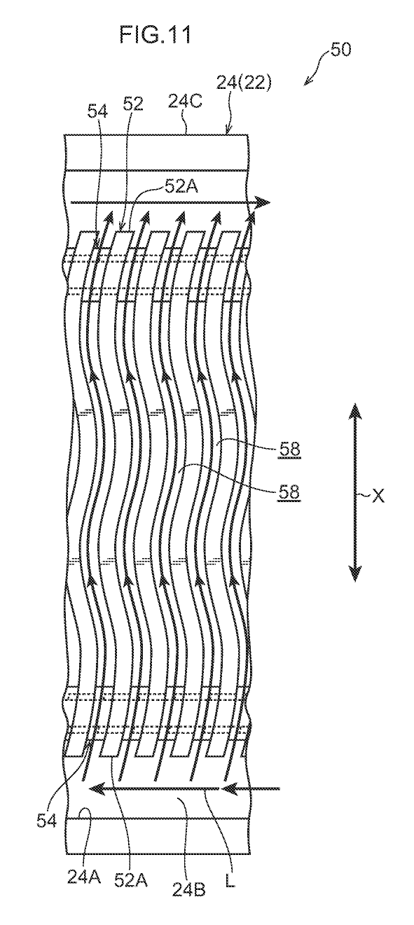

As illustrated in FIG. 11, the fins 52 each have a wave plate shape, and therefore have a wider plate face surface area, namely, a wider heat dissipating surface area, than the fins 30 of the first exemplary embodiment. Thus, heat in the fins 52 is efficiently captured by coolant flowing along flow paths 58 formed between adjacent fins 52. The cooling performance of the cooling device 50 is thereby improved. Note that the flow of coolant is indicated by the arrows L in FIG. 11.

Note that the cooling device 50 of the present exemplary embodiment may be manufactured by the same manufacturing method as the manufacturing method of the cooling device 20 of the first exemplary embodiment.

In the cooling device 50 of the present exemplary embodiment, the fins 52 each have an elongated wave plate shape; however, the present invention is not limited to this configuration. For example, the fins 52 may each have a zigzagged plate shape or a rectangular wave plate shape. Note that the shape of the fins 52 in the second exemplary embodiment may also be applied the each fins described later in the second, third, fifth, and sixth exemplary embodiments.

### Third Exemplary Embodiment

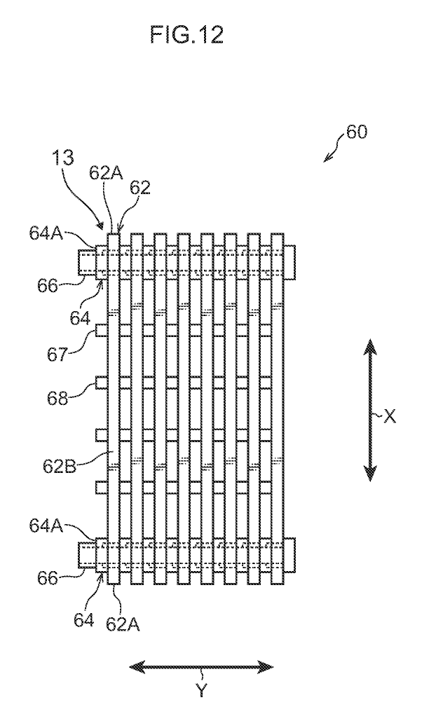

FIG. 12 to FIG. 15 illustrate a cooling device 60 of the third exemplary embodiment. Note that the cooling device 60 of the present exemplary embodiment has a similar configuration to the cooling device 20 of the first exemplary embodiment excluding the configuration of fins 62, and so similar explanation is omitted. Note that similar configuration to the first exemplary embodiment is appended with the same reference numerals.

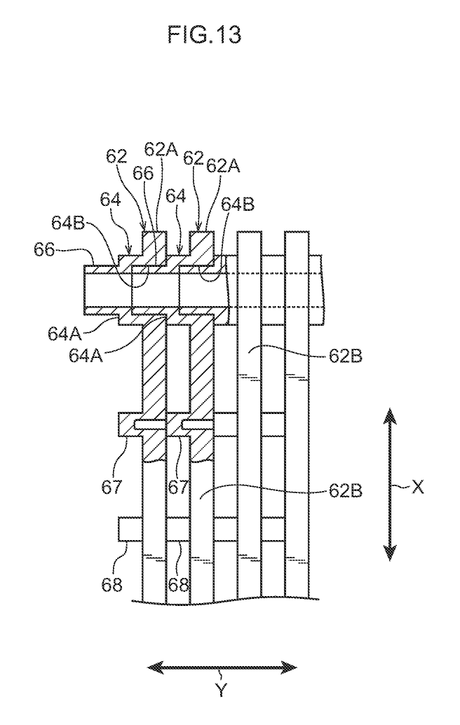

As illustrated in FIG. 12 to FIG. 14, each fin 62 has an elongated flat plate shape. Note that the fin length direction of the fins 62 of the present exemplary embodiment is the same direction as the device width direction. Tube shaped (circular tube shaped in the present exemplary embodiment) projecting portions 64, and tube shaped (circular tube shaped in the present exemplary embodiment) bulge portions 66 that project out from apex portions 64A of the projecting portions 64, are each formed by pressing at both end portion 62A sides in the fin length direction of each fin 62. The insertion portions 64B configured at an interior of the projecting portions 64 are each inserted with the bulge portions 66 of the fin 62 that is adjacent at the other side (the right in FIG. 12 and FIG. 13) in the fin array direction.

Ridge portions 67 and ridge portions 68 that each project out in the fin plate thickness direction at the same side as the projection side of the projecting portions 64 are each formed on each fin 62. Each ridge portion 67 extends in a straight line from one end face 62B toward another end face 62B side in the fin width direction of the fin 62, and terminates partway. Each ridge portion 68 extends in a straight line from the other end face 62B toward the one end face 62B side in the fin width direction of the fin 62, and terminates partway.

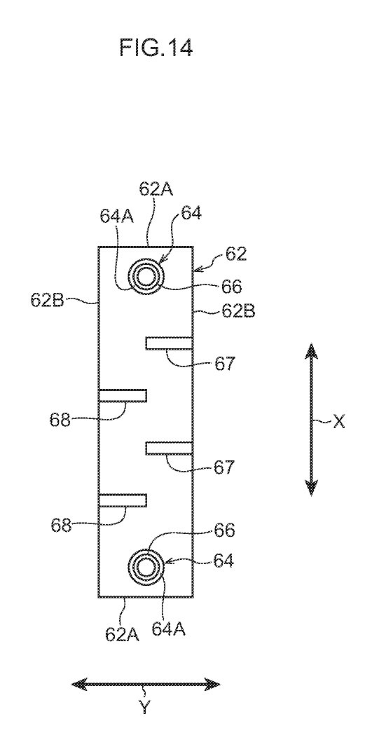

As illustrated in FIG. 14, the ridge portions 67 and the ridge portions 68 are formed alternately in the fin length direction with a separation therebetween.

As illustrated in FIG. 12 and FIG. 13, in the present exemplary embodiment, the ridge portions 67 and the ridge portions 68 each abut an adjacent fin 62. Flow paths 69 (flow paths that snake along the device thickness direction (fin width direction)) are thereby formed snaking between adjacent fins 62.

Next, explanation follows regarding operation and advantageous effects of the cooling device 60 of the present exemplary embodiment. Note that explanation regarding operation and advantageous effects that are similar to the operation and advantageous effects obtained in the first exemplary embodiment is omitted.

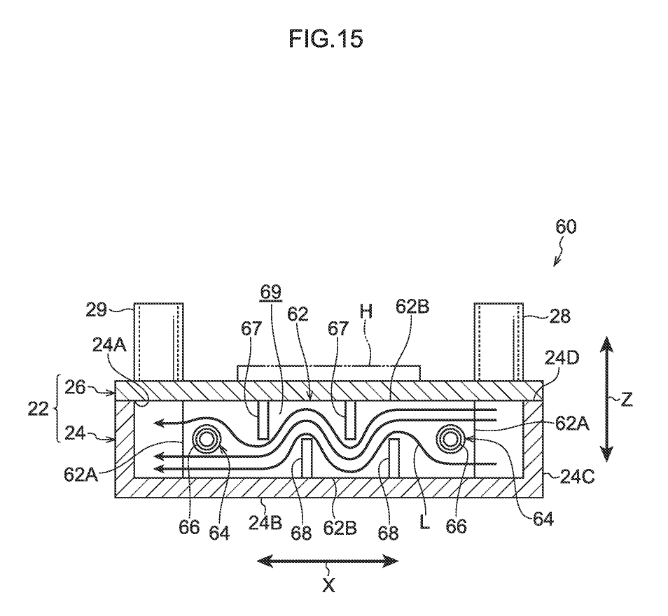

As illustrated in FIG. 15, the ridge portions 67 and the ridge portions 68 that abut an adjacent fin 62 are formed on each fin 62, thereby forming the flow paths 69 that snake between adjacent fins 62, such that a turbulent flow occurs in the coolant flowing along the flow paths 69. The advantageous effect in which coolant captures heat from the fins 62 (cooling the fins 62) is improved by the turbulent flow occurring in this manner. Thus, the cooling performance of the cooling device 60 is improved. Note that the flow of coolant is indicated by the arrows L in FIG. 15.

Note that the cooling device 60 of the third exemplary embodiment may be manufactured by the same manufacturing method as the manufacturing method of the cooling device 20 of the first exemplary embodiment.

The cooling device 60 of the third exemplary embodiment is configured such that the ridge portions 67 and the ridge portions 68 each extend in a straight line; however, the present invention is not limited to this configuration. For example, the ridge portions 67 and the ridge portions 68 may each be configured extending in a curved shape, a zigzagged shape, or a stepped shape. The ridge portions 67 and the ridge portions 68 may alternatively each be formed in a column shape (such as a circular column shape).

### Fourth Exemplary Embodiment

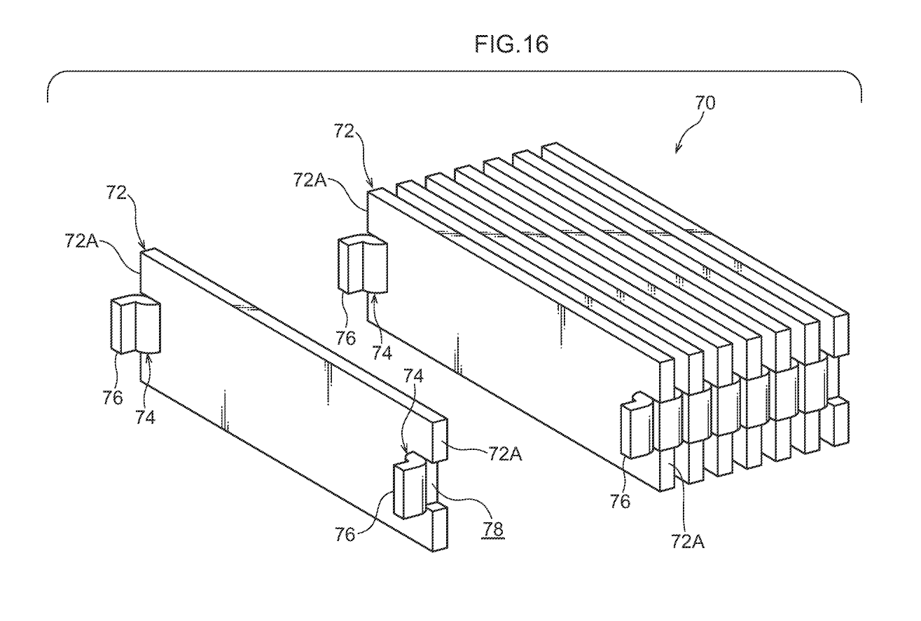

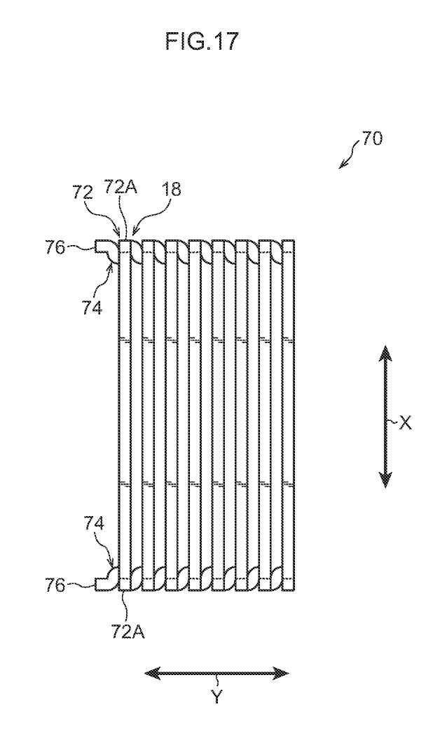

FIG. 16 to FIG. 19 illustrate a cooling device 70 of the fourth exemplary embodiment. Note that the cooling device 70 of the present exemplary embodiment has a similar configuration to the cooling device 20 of the first exemplary embodiment excluding the configuration of fins 72, and so similar explanation is omitted. Note that similar configuration to the first exemplary embodiment is appended with the same reference numerals.

As illustrated in FIG. 16 to FIG. 18, each fin 72 has an elongated flat plate shape. Note that the fin length direction of the fins 72 of the present exemplary embodiment is the same direction as the device width direction. Projecting portions 74, these being cut and raised portions formed by cutting and raising part of each fin 72 by pressing, are each formed at both end portion 72A sides in the fin length direction of each fin 72. Each projecting portion 74 includes an upstand portion 74A that stands out in the fin plate thickness direction, and a seat portion 74B that extends from a leading end portion of the upstand portion 74A toward the fin length direction outside. Note that in the present exemplary embodiment, an apex portion 74C of the projecting portion 74 is configured by the seat portion 74B.

The seat portion 74B is formed with a bulge portion 76 that projects out in the fin plate thickness direction at a position separated from the upstand portion 74A, at the fin length direction outside thereof, by a specific distance. Note that in the present exemplary embodiment, the bulge portion 76 is formed at a position separated from the upstand portion 74A, at the fin length direction outside thereof, by an amount corresponding to the plate thickness of the fin 72.

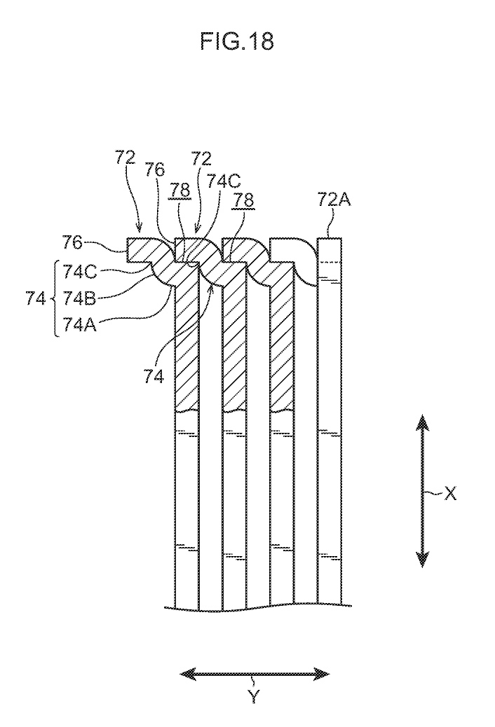

The fin 72 is also formed with an opening 78, serving as an insertion portion for the portion forming the projecting portion 74, namely, the portion that was partially cut and raised. The each bulge portion 76 of the fin 72 that is adjacent at the other side (the right in FIG. 18) in the fin array direction is inserted into the opening 78.

Next, explanation follows regarding a working process and an assembly process of a manufacturing method of the cooling device 70 of the fourth exemplary embodiment. Note that the installation process of the manufacturing method of the cooling device 20 of the first exemplary embodiment may be employed as an installation process, and so explanation of this is omitted.

### Working Process

First, notches are made in each un-processed fin 72 formed of metal material in a plate shape. Then, a portion surrounded by the notches is bent into a crank shape or an S shape in the fin plate thickness direction while being made to upstand (raised) by pressing, thereby forming each projecting portion 74 configured with the upstand portion 74A and the seat portion 74B, and forming the bulge portion 76 on the seat portion 74B. The opening 78 serving as the insertion portion is also formed on the portion of the fin 72 that has been partially cut and raised. Thus, the bulge portions 76 of each work-processed fin 72 can be inserted into the openings 78 of another work-processed fin 72. The upstand portions 74A, the seat portions 74B, and the bulge portions 76 are each formed at both end portion 72A sides in the fin length direction of the un-processed fins 72.

Note that “un-processed fin 72” refers to a state of each fin 72 prior to the working process (prior to forming the notches in the present exemplary embodiment). Moreover, “work-processed fin 72” refers to a state of each fin 72 after the working process (after the projecting portions 74 and the bulge portions 76 have been formed in the present exemplary embodiment). Note that the work-processed fin 72 is simply referred to as fin 72.

### Assembly Process

Next, as illustrated in FIG. 18, the bulge portions 76 of each fin 72 are each inserted into the openings 78 of another fin 72. When this is performed, the fins 72 are assembled to each other by each inserting the bulge portions 76 of each fin 72 into the openings 78 of another fin 72 until the apex portions 74C (seat portions 74B) of the projecting portions 74 of the fin 72 abut the other fin 72.

Note that in the assembly process, the apex portions 74C of the projecting portions 74 of each fin 72 are made to abut another fin 72 and the fins 72 are assembled together in a state in which relative movement (relative movement in a direction orthogonal to the fin plate thickness direction in the present exemplary embodiment) of the fins 72 has been restrained due to the bulge portions 76 of the fin 72 being inserted into the openings 78 of the other fin 72. This enables the positioning of the fins 72 to be easily performed. A separation between the fins 72 is also secured (maintained) by the projecting portions 74.

The cooling device 70 is completed by installing the fins 72 that have been assembled in this manner to the case 22 in the installation process.

Next, explanation follows regarding operation and advantageous effects of the cooling device 70 of the present exemplary embodiment. Note that explanation regarding operation and advantageous effects that are similar to the operation and advantageous effects obtained in the first exemplary embodiment is omitted.

In the cooling device 70 of the present exemplary embodiment, each fin 72 is partially cut and raised to form the projecting portion 74, the bulge portion 76, and the opening 78, thereby enabling the projecting portion 74, the bulge portion 76, and the opening 78 to be formed at the fin 72 more simply and at a lower cost than, for example, configurations in which the projecting portion 74, the bulge portion 76, and the opening 78 are formed at the fin 72 while the fin 72 is formed by machining.

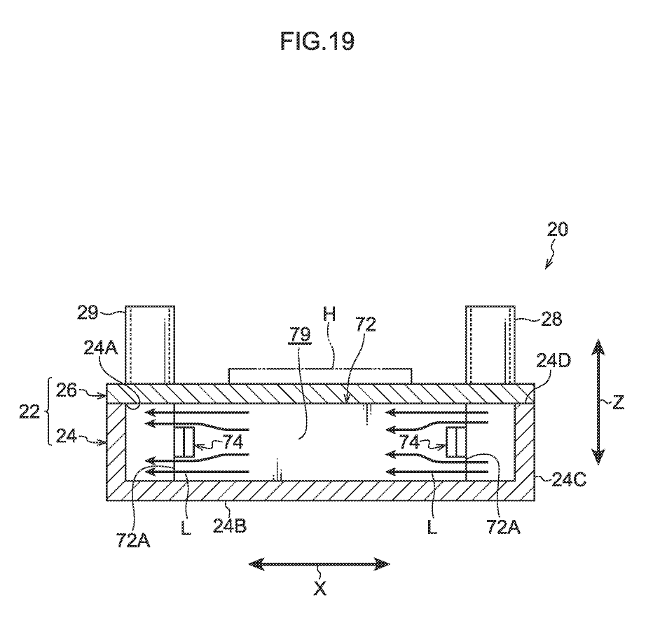

Note that similarly to the cooling device 20 of the first exemplary embodiment, as illustrated in FIG. 19, flow paths 79 are formed between adjacent fins 72 in the cooling device 70.

### Fifth Exemplary Embodiment

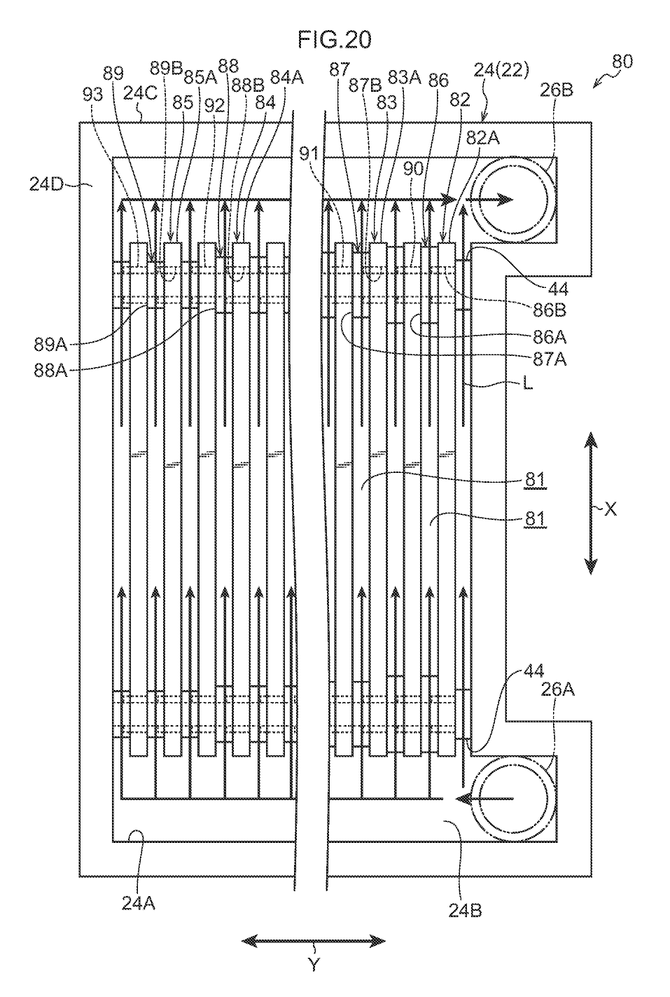

FIG. 20 illustrates a cooling device 80 of the fifth exemplary embodiment. Note that the cooling device 80 of the present exemplary embodiment has a similar configuration to the cooling device 20 of the first exemplary embodiment excluding the configuration of fins 82 to 85, and so similar explanation is omitted. Note that similar configuration to the first exemplary embodiment is appended with the same reference numerals.

As illustrated in FIG. 20, in the cooling device 80 of the present exemplary embodiment, plural of each of plural types (four types in the present exemplary embodiment) of the fins 82 to 85 are employed. The fins 82 are disposed in a region that is nearest to the supply port 26A. The fins 85 are disposed in a region that is furthest from the supply port 26A. The fins 83 are disposed adjacent to the region in which the fins 82 are disposed, and the fins 84 are disposed adjacent to the region in which the fins 85 are disposed.

The fins 82 to 85 of the present exemplary embodiment each have an elongated flat plate shape. Note that the fin length direction of each of the fins 82 to 85 of the present exemplary embodiment is the same direction as the device width direction. Circular tube shaped projecting portions 86 to 89, and circular tube shaped bulge portions 90 to 93 that project out from apex portions 86A to 89A of the each projecting portions 86 to 89, are each formed at both end portion 82A to 85A sides in the fin length direction of each of the fins 82 to 85. Bulge portions of an adjacent fin are each inserted into insertion portions 86B to 89B configured at an interior of the each projecting portions 86 to 89. Note that in the present exemplary embodiment, outer diameters of the bulge portions 90 to 93 are all set to be the same. Inner diameters of the insertion portions 86B to 89B are also are all set to be the same.

An outer diameter of the projecting portions 86 of each fin 82 is set larger than an outer diameter of the projecting portions 87 of each fin 83. The outer diameter of the projecting portions 87 of each fin 83 is set larger than an outer diameter of the projecting portions 88 of each fin 84. The outer diameter of the projecting portions 88 of each fin 84 is set larger than an outer diameter of the projecting portions 88 of each fin 84. Namely, fins disposed in regions nearer to the supply port 26A are set with projecting portions with a larger outer diameter.

Next, explanation follows regarding operation and advantageous effects of the cooling device 80 of the present exemplary embodiment. Note that explanation regarding operation and advantageous effects that are similar to the operation and advantageous effects obtained in the first exemplary embodiment is omitted.

As illustrated in FIG. 20, in the cooling device 80, the outer diameter of the projecting portions 86 of the fins 82 disposed in the region near to the supply port 26A is set larger than the outer diameter of the projecting portions 87 of the fins 83 disposed in a region that is further away from the supply port 26A than the fins 82. Thus, an entrance to a gap (flow path 81) formed between adjacent fins 83 is wider than an entrance to a gap (flow path 81) formed between adjacent fins 82. Thus, coolant that has been supplied through the supply port 26A also flows into the flow paths 81 at positions far away from the supply port 26A along the device depth direction. Namely, since the coolant travels as far as a back side (the opposite side to the supply port 26A) in the device depth direction of the case 22, an advantageous effect of regulating the coolant in the cooling device 80 is further obtained. Note that the flow of coolant is indicated by the arrows L in FIG. 20.

Note that the cooling device 80 of the fifth exemplary embodiment may be manufactured by the same manufacturing method as the manufacturing method of the cooling device 20 of the first exemplary embodiment.

### Sixth Exemplary Embodiment

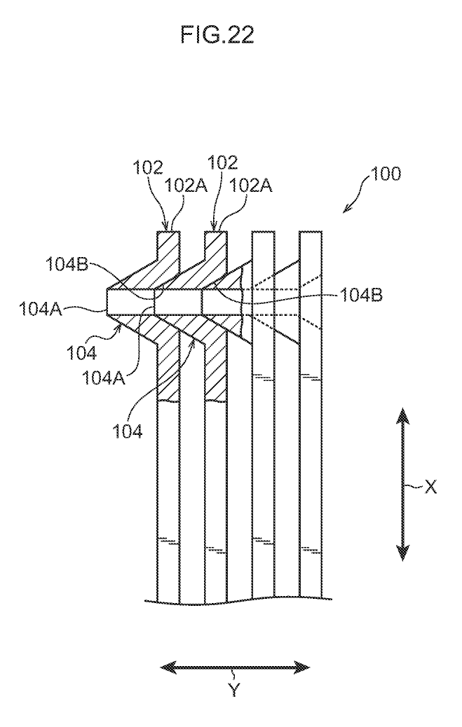

FIG. 22 illustrates a cooling device 100 of the sixth exemplary embodiment. Note that the cooling device 100 of the present exemplary embodiment has a similar configuration to the cooling device 20 of the first exemplary embodiment excluding the configuration of fins 102, and so similar explanation is omitted.

As illustrated in FIG. 22, each fin 102 has an elongated flat plate shape. Note that the fin length direction of the fins 102 of the present exemplary embodiment is the same direction as the device width direction. Conical tube shaped projecting portions 104 formed by pressing are formed at both end portion 102A sides in the fin length direction of each fin 102. An insertion portion 1048 configured at an interior of the projecting portion 104 is each inserted with a leading end portion 104A of the each projecting portion 104 of the fin 102 that is adjacent at the other side (the right in FIG. 22) in the fin array direction.

Thus, in a state in which the leading end portions 104A of the projecting portions 104 of the fin 102 that is adjacent at the other side (the right in FIG. 22) in the fin array direction have been each inserted into the insertion portions 1048 of the each fin 102, relative movement (relative movement in a direction orthogonal to the fin plate thickness direction in the present exemplary embodiment) of adjacent fins 102 is restrained. In the above-described state, the height (projection height) of the projecting portions 104 is set such there is a separation formed between adjacent fins 102.

Note that the fins 102 of the present exemplary embodiment are an example of a maintaining means of the present invention, and the insertion portions 1048 of the present exemplary embodiment are an example of a restraining means of the present invention.

Next, explanation follows regarding operation and advantageous effects of the cooling device 100 of the present exemplary embodiment. Note that explanation regarding operation and advantageous effects that are similar to the operation and advantageous effects obtained in the first exemplary embodiment is omitted.

As illustrated in FIG. 22, the cooling device 100 is configured such that the conical tube shaped projecting portions 104 are formed at each fin 102, and the leading end portions 104A of the projecting portions 104 are each inserted into the insertion portions 1048 of another fin 102, such that the work-processed shape of the projecting portions 104 is simpler than in the first exemplary embodiment and the fourth exemplary embodiment, thereby enabling manufacturing costs to be suppressed.

Note that the cooling device 100 of the sixth exemplary embodiment may be manufactured by the same manufacturing method as the manufacturing method of the cooling device 20 of the first exemplary embodiment.

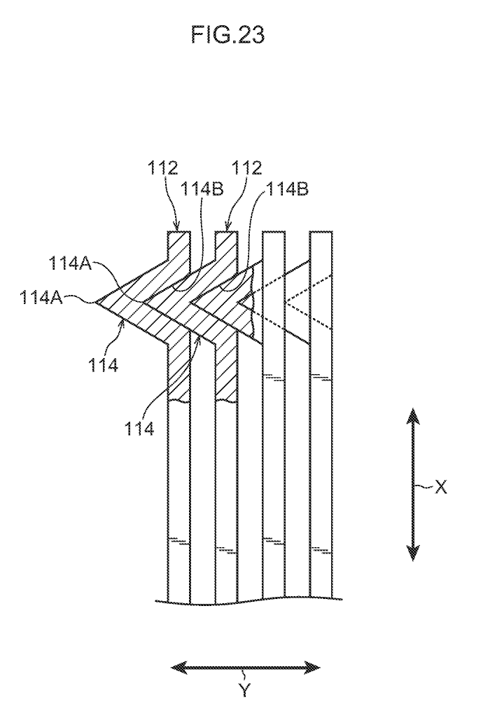

In the present exemplary embodiment, as illustrated in FIG. 22, each projecting portion 104 is formed in a conical tube shape; however, the present invention is not limited to this configuration. For example, as in fins 112 illustrated in FIG. 23, these being a first modified example of the fins 102, a configuration may be applied in which a leading end portion 114A of each conical tube shaped projecting portion 114 is closed off, namely, the projecting portion 114 is pressed out into a conical shape by pressing. Insertion portions 1148 configured at an interior of the each projecting portions 114 are each inserted with the leading end portions 114A of the projecting portions 114 of the fin 112 that is adjacent at the other side (the right in FIG. 23) in the fin array direction. Note that there is no need for a pilot hole when work-processing the bulge portion 114, thereby enabling the number of processes for work-processing the fins 112 of the first modified example to be reduced. This also enables scrap material created by forming the pilot holes in the un-processed fins 112 to be reduced.

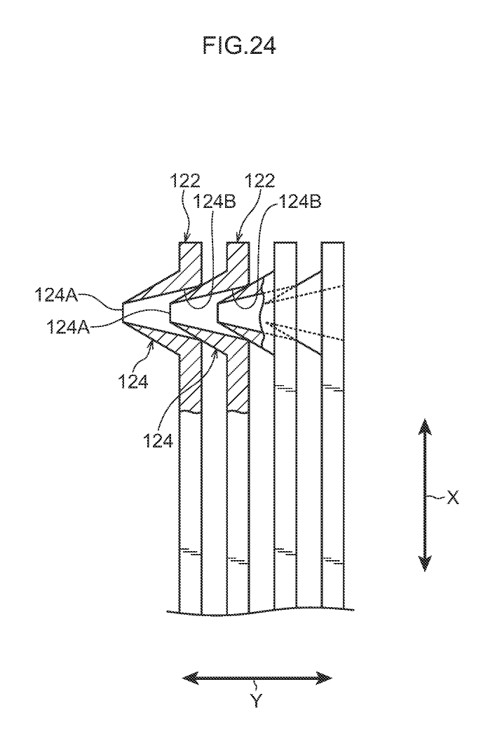

In the present exemplary embodiment, as illustrated in FIG. 22, the projecting portions 104 are formed at each fin 102 by pressing; however, the present invention is not limited to this configuration. For example, as illustrated in FIG. 24, each projecting portion 124, this being a conical tube shaped protruding portion at an edge of a through-hole, may be formed at a fin 122 by die cutting (punching). Insertion portions 1248 configured at an interior of the each projecting portions 124 are each inserted with leading end portions 124A of the projecting portions 124 of the fin 122 that is adjacent at the other side (the right in FIG. 24) in the fin array direction. Note that there is no need for a pilot hole when work-processing the bulge portion 124, thereby enabling the number of processes for work-processing the fins 122 of the second modified example to be reduced.

The present invention has been explained above with reference to exemplary embodiments; however, these exemplary embodiments are merely examples, and various modifications may be implemented within a range not departing from the spirit of the present invention. Obviously, the scope of rights of the present invention is not limited by these exemplary embodiments.

The entire content of the disclosure of Japanese Patent Application No. 2014-034508 filed Feb. 25, 2014 is incorporated by reference in the present specification.

All publications, patent applications and technical standards mentioned in the present specification are incorporated by reference in the present specification to the same extent as if the individual publication, patent application, or technical standard was specifically and individually indicated to be incorporated by reference.

1. A cooling device comprising:
a case that includes a supply port for supplying coolant to an interior of the case and a discharge port for discharging coolant at the interior of the case to an exterior of the case;
fins that each have a plate shape, that are arrayed at the interior of the case at separations along a plate thickness direction, and that have coolant flowing between adjacent fins;
a maintenance portion that is formed at the fins and that maintains a separation between the adjacent fins; and
a restraint portion that is formed at the fins and that restrains relative movement of the adjacent fins being maintained at the separation by the maintenance portion.

2. The cooling device of claim 1, wherein:
the maintenance portion includes a projecting portion that projects out in the plate thickness direction of the fins and that has an apex portion that abuts a fin that is adjacent at one side in an array direction of the fins; and
the restraint portion includes a bulge portion that projects out from the apex portion of the projecting portion and an insertion portion into which the bulge portion of a fin that is adjacent at another side in the array direction of the fins is inserted.

3. The cooling device of claim 2, wherein:
the projecting portion is a tube shaped protruding portion formed by pressing the fins, and
an interior of the projecting portion configures the insertion portion.

4. The cooling device of claim 2, wherein the projecting portion, the bulge portion, and the insertion portion are each formed at both end portion sides along a length direction of the fins.

5. The cooling device of claim 1, wherein end faces of the fins are brazed to an inner face of the case.

6. A cooling device manufacturing method comprising:
assembling together fins that are plate shaped and each formed with a projecting portion projecting out in a plate thickness direction, a bulge portion projecting out from an apex portion of the projecting portion, and an insertion portion of a size enabling internal insertion of the bulge portion, wherein the fins are assembled together by inserting the bulge portion of one of the fins into the insertion portion of another of the fins, and abutting the projecting portion of the one fin against the other fin; and
installing the fins at an interior of a case including a supply port for supplying coolant to the interior of the case, and a discharge port for discharging coolant at the interior of the case to an exterior of the case.

7. The cooling device manufacturing method of claim 6, further comprising: prior to the assembling, forming a tube shaped protruding portion, serving as the projecting portion and including the insertion portion configured at an interior thereof, by pressing a plate shaped un-processed fin.

8. The cooling device manufacturing method of claim 7, wherein: in the forming of the protruding portion, forming each of the projecting portion, the bulge portion, and the insertion portion at both end portion sides along a length direction of the un-processed fins.

9. The cooling device manufacturing method of claim 6, comprising, in the installing of the fins, brazing end faces of the fins to an inner face of the case.
